(19) United States
(12) Patent Application Publication
(10) Pub. No.: US 2025/0133813 A1
(43) Pub. Date: Apr. 24, 2025

(54) METHOD AND STRUCTURE FOR IMPROVING ESD PERFORMANCE OF METAL-GATE HIGH-VOLTAGE DEVICES

(71) Applicant: Shanghai Huali Integrated Circuit Corporation, Shanghai (CN)

(72) Inventors: Zhi TIAN, Shanghai (CN); Junhui Pu, Shanghai (CN); Hua Shao, Shanghai (CN); Haoyu Chen, Shanghai (CN)

(73) Assignee: Shanghai Huali Integrated Circuit Corporation, Shanghai (CN)

(21) Appl. No.: 18/778,718

(22) Filed: Jul. 19, 2024

(30) Foreign Application Priority Data
Oct. 20, 2023 (CN) 202311369402.4

(51) Int. Cl. H01L 21/8238; H01L 21/762; H01L 27/092

(52) U.S. Cl. CPC H10D 84/038; H01L 21/76224; H10D 84/0188; H10D 84/85

(57) ABSTRACT

The present application provides a method and a structure for improving ESD performance of a metal-gate high-voltage device, wherein a first STI region and a second STI region are formed within the high voltage P-well; a first high-voltage region N-diffusion region is formed within the high voltage P-well between the first STI region and second STI region; the area immediately adjacent to the first STI region and the area immediately adjacent to the second STI region are filled with silicon oxide; the silicon oxide immediately adjacent to the first STI region is formed as a first silicon oxide structure, and the silicon oxide immediately adjacent to the second STI region is formed as a second silicon oxide structure; and an IO N-well is formed within the first high-voltage region N-diffusion region of the lower area between the first silicon oxide structure and second silicon oxide structure.

### CROSS-REFERENCE TO RELATED APPLICATIONS

This application claims priority to Chinese patent application No. 202311369402.4, filed on Oct. 20, 2023, the disclosure of which is incorporated herein by reference in entirety.

### TECHNICAL FIELD

The present application relates to the field of semiconductor technology and, in particular, to a method and a structure for improving ESD performance of a metal-gate high-voltage device.

### BACKGROUND

OLED, which is current-driven, has a current density based on a driving voltage across both ends thereof. The higher the voltage is, the higher the current density is. The voltage, current density and luminescence efficiency may have a relation that cannot be always maintained constantly due to the aging of OLED devices after a long-time use. The aging of OLED devices is characterized by a turn on voltage rise and a luminous efficiency reduction. A current flowing through OLED needs to be increased for the same luminous brightness, and thus, a high voltage device is required for OLED to realize a large current. In the 28 HV metal gate technology, there is a need to integrate low-voltage SRAM and high-voltage drive devices. However, a high voltage requires a thick silicon oxide gate, affecting a subsequent metal gate process. For compatibility with the metal gate technology, etch back for active regions is performed for high-voltage areas, and then thick silicon oxide is grown to have a height as close as possible to the height of the active regions.

28 nm-process high-voltage devices have a Field Diffusion Drain (FDD) structure, and sources and drains in the symmetric structure contain shallow trench isolation structures. When used as a high-voltage ESD device, 28 HV 32V devices, due to large sizes, and the largest base resistance of a parasitic BJT of a center finger, are firstly activated in ESD to limit a voltage to Vholding. If a trigger voltage 2 (Vtrigger2) is less than a trigger voltage 1 (Vtrigger1), other fingers would not be activated. To address this problem, Tai-Hsiang Lai. et. al. propose that a drain end of an ESD circuit is injected with a N-well of an original MV device because an ion implantation depth and a doping concentration for IONW (N-well doping of medium voltage devices) is greater than that of HVNDF (high-voltage region N-type diffusion) of an original high voltage device. There is an advantage where a corresponding trigger voltage is reduced, and a holding voltage is reduced to prevent parasitic latch-up, and a total amount of It2 is increased. The reason is the following: the trigger voltage is lowered, mainly due to the transfer of the junctions of original HVNDF (high-voltage region N-type diffusion) and HVPW (high-voltage P-well) to IONW (N-well doping in medium-voltage devices) and HVPW (high-voltage P-well), and the corresponding junction collapse voltage is lowered due to a relatively high doping concentration for IONW. A retention voltage is increased, wherein the high concentration for IONW reduces a corresponding trigger voltage thereof, and prevents a Kirk effect caused by large currents, thus increasing the corresponding retention voltage. Moreover, since corresponding IONW is relatively deep, a bleeder current therein can be far away from original shallow trench isolation, thus improving the uniformity of the current, and the bleeder current capability is proportional to a width. However, this structure requires that corresponding IONW has a doping concentration higher than that of HVNDF, but has a depth lower than that of HVNDF, failing to achieve desired results. Additional mask plates and corresponding process development are required to achieve the same effect.

### BRIEF SUMMARY

The present application provides a structure and a method for improving ESD performance of metal-gate high-voltage devices, for solving the problem in the prior art that a Kirk effect due to large currents causes a junction to be transferred from a high-voltage N-diffusion region or a high-voltage P-well to a high-voltage P-well or a source-drain region N-type doped region when high-voltage devices using field diffusion process structures are activated with ESD trigging.

The present application provides a method for improving ESD performance of a metal-gate high-voltage device, comprising:
step I. providing a P-substrate, and forming a high voltage P-well on the P-substrate;
step II. forming a first STI region and a second STI region spaced apart from each other within the high voltage P-well, wherein the high voltage P-well between the first STI region and the second STI region, and the high voltage P-well on side of the first STI region, and the high voltage P-well on side of the second STI region away from the first STI region, are active regions;
Step III. forming a first high-voltage region N-diffusion region within the high voltage P-well between the first STI region, and second STI region;
Step IV. etching the active region between the first STI region and second STI region to form recesses in the area immediately adjacent to the first STI region and the area immediately adjacent to the second STI region between the first STI region and second STI region; and etching the active region at the side of the first STI region away from the second STI region and the active region at the side of the second STI region away from the first STI region to form a recess;
Step V. filling the recesses with silicon oxide, wherein the silicon oxide in the recess in the side of the first STI region away from the second STI region and the silicon oxide in the recess in the side of the second STI region away from the first STI region are formed as a gate oxide layer; and the silicon oxide in the recess immediately adjacent to the first STI region between the first STI region and second STI region is formed as a first silicon oxide structure, and the silicon oxide in the recess immediately adjacent to the second STI region between the first STI region and second STI region is formed as a second silicon oxide structure; and
Step VI. forming an IO N-well within the first high-pressure region N-diffusion region of the lower area between the first silicon oxide structure and second silicon oxide structure.

According to one embodiment, a third STI region and a fourth STI region are also formed within the high voltage P-well in step II, wherein the third STI region is located at a side of the first STI region away from the second STI region, the fourth STI region is located at a side of the second STI region away from the first STI region, and the high voltage P-well between the third STI region and first STI region and the high voltage P-well between the second STI region and fourth STI region are active regions.

According to one embodiment, in step III, a second high-voltage region N-diffusion region and a first high-voltage region P-diffusion region adjacent to each other are formed in the active region between the third STI region and first STI region; and a third high-voltage region N-diffusion region and a second high-pressure region P-diffusion region adjacent to each other are formed in the active region between the second STI region and fourth STI region.

According to one embodiment, the method further comprises VII. forming a metal gate on the gate oxide layer.

According to one embodiment, the method further comprises step VIII. forming a first SDN region in the first high-voltage region N-diffusion region between the first silicon oxide structure and second silicon oxide structure; forming a second SDN region on the second high-voltage region N-diffusion region; forming a third SDN region on the third high-voltage region N-diffusion region; and forming a first SDP region in the first high voltage region P-diffusion region, and forming a second SDP region in the second high voltage region P-diffusion region.

The present application provides a structure for improving ESD performance of a metal-gate high voltage device, comprising at least:
a P-substrate, and a high voltage P-well located on the P-substrate; a first STI region, a second STI region, a third STI region, and a fourth STI region spaced apart from each other within the high voltage P-well; wherein the third STI region is located at a side of the first STI region away from the second STI region, and the fourth STI region is located at a side of the second STI region away from the first STI region; the high voltage P-well between the first STI region and the second STI region, and the high voltage P-well on side of the first STI region away from the second STI region, and the high voltage P-well on side of the second STI region away from the first STI region, are active regions; and the high voltage P-well between the third STI region and first STI region and the high voltage P-well between the second STI region and fourth STI region are active regions; and a first high-voltage region N-diffusion region formed within the high voltage P-well between the first STI region and second STI region; and
the active region at the side of the first STI region away from the second STI region and the active region at the side of the second STI region away from the first STI region being formed with a gate oxide layer; and the active region immediately adjacent to the first STI region between the first STI region and second STI region being formed with a first silicon oxide structure, and the active region immediately adjacent to the second STI region between the first STI region and the second STI region being formed with a second silicon oxide structure; and;
an IO N-well being formed within the first high-pressure region N-diffusion region of the lower area between the first silicon oxide structure and second silicon oxide structure.

According to one embodiment, the active region between the third STI region and first STI region is formed with a second high-voltage region N-diffusion region and a first high-voltage region P-diffusion region adjacent to each other; and the active region between the second STI region and fourth STI region is formed with a third high-voltage region N-diffusion region and a second high-voltage region P-diffusion region adjacent to each other.

According to one embodiment, a metal gate is formed on the gate oxide layer.

According to one embodiment, the first high-voltage region N-diffusion region between the first silicon oxide structure and second silicon oxide structure is formed with a first SDN region; the second high-voltage region N-diffusion region is formed with a second SDN region; the third high-voltage region N-diffusion region is formed with a third SDN region; and the first high-voltage region P-diffusion region is formed with a first SDP region, and the second high-pressure region P-diffusion region is formed with a second SDP region.

As described above, the structure and method of the present application for improving ESD performance of a metal-gate high-voltage device has the following beneficial effects. Ion implantation such as IO N-wells introduced in the present application has a depth larger than that of an active region etch back area to enhance N-type doping in the area, facilitating kirk-effect suppression. Since a utilized active region etch back area which may form a channel restricting a current allows a corresponding current to flow along a heavily doped area to a high voltage P-well area, non-uniform conduction problems due to current crowding at a STI corner can be prevented. The application allows no increase in a layout area by utilizing an original STI region, and at the same time, is compatible with an existing process with no newly added mask plate.

### BRIEF DESCRIPTION OF THE DRAWINGS

FIG. 1 shows a flowchart of the method for improving ESD performance of a metal-gate high voltage device of the present application; and

FIG. 2 shows a cross-sectional schematic view of a structure for improving ESD performance of a metal-gate high-voltage device of the present application.

### DETAILED DESCRIPTION OF THE DISCLOSURE

Embodiments of the present application are described below by specific examples. Other advantages and effects of the application can be readily appreciated by those skilled in the art from the disclosure in the description. The present application may also be implemented or applied in various other specific embodiments, and various details in this description may be modified or changed based on different views and applications without departing from the spirit of the application.

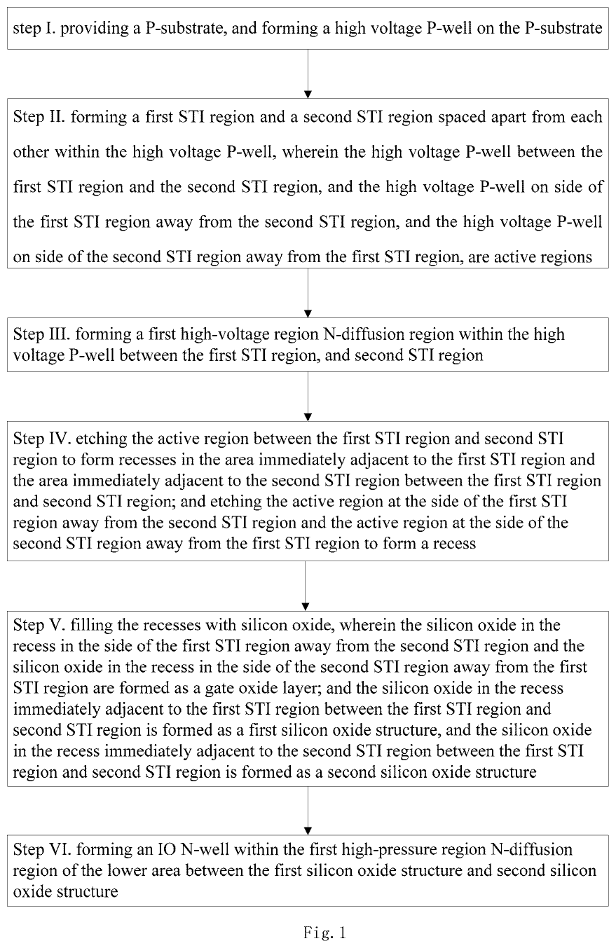

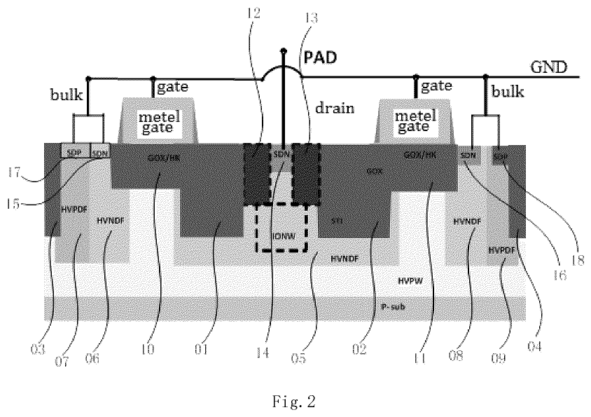

Please refer to FIGS. 1 to 2. It should be noted that the views in the embodiments are only to schematically illustrate the basic concept of the present application. Thus, the views only illustrate the components related to the present application, not drawn in accordance with the number, shapes, and dimensions of the components in practical implementations in which the components may be arbitrarily changed in terms of forms, numbers, and ratios, and may have a more complex layout.

The present application provides a method for improving ESD performance of a metal-gate high-voltage device, referring to FIG. 1, it shows a flowchart of the method for improving ESD performance of a metal-gate high voltage device of the present application, and the method includes at least the following steps.

The method includes step I. providing a P-substrate, and forming a high voltage P-well on the P-substrate.

Referring to FIG. 2, it shows a cross-sectional schematic view of a structure for improving ESD performance of a metal-gate high-voltage device of the present application, wherein in step I, a P-substrate (P-sub) is provided, and a high voltage P-well (HVPW) is formed on the P-substrate (P-sub).

The method includes step II. forming a first STI region and a second STI region spaced apart from each other within the high voltage P-well, wherein the high voltage P-well between the first STI region and the second STI region, and the high voltage P-well on side of the first STI region away from the second STI region, and the high voltage P-well on side of second STI region away from the first STI region, are active regions.

Further, a third STI region and a fourth STI region are also formed within the high voltage P-well in step II, wherein the third STI region is located at a side of the first STI region away from the second STI region, the fourth STI region is located at a side of the second STI region away from the first STI region, and the high voltage P-well between the third STI region and the first STI region and the high voltage P-well between the second STI region and the fourth STI region are active regions.

Referring to FIG. 2, in step II, a first STI region 01 and a second STI region 02 spaced apart from each other are formed within the high voltage P-wells (HVPW); the high voltage P-well (HVPW) between the first STI region 01 and the second STI region 02, and the high voltage P-well (HVPW) on side of the first STI region 01 away from the second STI region, and the high voltage P-well (HVPW) on side of the second STI region 02 away from the first STI region 01, are active regions; a third STI region 03 and a fourth STI region 04 are also formed within the high voltage P-well (HVPW), wherein the third STI region 03 is located at the side of the first STI region 01 away from the second STI region 02, the fourth STI region 04 is located at the side of the second STI region 02 away from the first STI region 01, and the high voltage P-well (HVPW) between the third STI region 03 and the first STI region 01 and the high voltage P-well (HVPW) between the second STI region 02 and the fourth STI region 04 are active regions.

The method includes step III. forming a first high-voltage region N-diffusion region within the high voltage P-type well between the first STI region, and second STI region.

Further, in step III of the embodiment, a second high-voltage region N-diffusion region and a first high-voltage region P-diffusion region adjacent to each other are formed in the active region between the third STI region and first STI region; and a third high-voltage region N-diffusion region and a second high pressure region P-diffusion region adjacent to each other are formed in the active region between the second STI region and fourth STI region. Referring to FIG. 2, in the step III, a first high-voltage region N-diffusion region (HVNDF) 05 is formed within the high voltage P-well (HVPW) between the first STI region 01, and second STI region 02; a second high-voltage region N-diffusion region (HVNDF) 06 and a first high-voltage region P-diffusion region (HVPDF) 07 adjacent to each other are formed in the active region between the third STI region 03 and first STI region 01; and a third high-pressure region N-diffusion region (HVNDF) 08 and a second high-pressure region P-diffusion region (HVPDF) 09 adjacent to each other are formed in the active region between the second STI region 02 and fourth STI region 04.

The method includes step IV. etching the active region between the first STI region and second STI region to form recesses in the area immediately adjacent to the first STI region and the area immediately adjacent to the second STI region between the first STI region and second STI region; and etching the active region at the side of the first STI region away from the second STI region and the active region at the side of the second STI region away from the first STI region to form a recess. Referring to FIG. 2, in step IV, the active region between the first STI region 01 and second STI region 02 is etched to form recesses in the area immediately adjacent to the first STI region 01 and the area immediately adjacent to the second STI region 02 between the first STI region 01 and second STI region 02 (recesses not shown in FIG. 2); and the active region at the side of the first STI region 01 away from the second STI region 02 and the active region at the side of the second STI region 02 away from the first STI region 01 are etched to form recesses (recesses not shown in FIG. 2).

The method includes step V. filling the recesses with silicon oxide, wherein the silicon oxide in the recess in the side of the first STI region away from the second STI region and the silicon oxide in the recess in the side of the second STI region away from the first STI region are formed as a gate oxide layer; and the silicon oxide in the recess immediately adjacent to the first STI region between the first STI region and second STI region is formed as a first silicon oxide structure, and the silicon oxide in the recess immediately adjacent to the second STI region between the first STI region and second STI region is formed as a second silicon oxide structure. Referring to FIG. 2, in step V, the recesses are filled with silicon oxide, wherein the silicon oxide in the recess in the side of the first STI region 01 away from the second STI region 02 and the silicon oxide within the recess in the side of the second STI region 02 away from the first STI region 01 are formed as a gate oxide layer, that is, the silicon oxide in the recess in the side of the first STI region 01 away from the second STI region 02 is formed as a gate oxide layer (GOX/HK) 10, and the silicon oxide in the recess in the side of the second STI region 02 away from the first STI region 01 is formed as a gate oxide layer (GOX/HK) 11.

The silicon oxide in the recess immediately adjacent to the first STI region 01 between the first STI region 01 and second STI region 02 is formed as a first silicon oxide structure 12, and the silicon oxide in the recess immediately adjacent to the second STI region 02 between the first STI region 01 and second STI region 02 is formed as a second silicon oxide structure 13.

The method includes step VI. forming an IO N-well within the first high-pressure region N-diffusion region of the lower area between the first silicon oxide structure and second silicon oxide structure. Referring to FIG. 2, in step VI, an IO N-well (IONW) is formed within the first high-pressure region N-diffusion region 05 of the lower area between the first silicon oxide structure 12 and second silicon oxide structure 13.

Referring to FIG. 2, further, the method of the present embodiment further comprises step VII. forming a metal gate on the gate oxide layer. Still further, the method of the present embodiment further comprises step VIII. forming a first SDN region (SDN) 14 in the first high-voltage region N-diffusion region 05 between the first silicon oxide structure 12 and second silicon oxide structure 13; forming a second SDN region 15 on the second high-voltage region N-diffusion region 06; forming a third SDN region 16 on the third high-voltage region N-diffusion region 08; and forming a first SDP region 17 in the first high voltage region P-diffusion region 07, and forming a second SDP region 18 in the second high voltage region P-diffusion region 09.

The present application also provides a structure for improving ESD performance of a metal-gate high voltage device, referring to FIG. 2, comprising at least:
a P-substrate (P-sub), and a high voltage P-well located on the P-substrate; a first STI region 01, a second STI region 02, a third STI region 03, and a fourth STI region 04 spaced apart from each other within the high voltage P-well (HVPW); wherein the third STI region 03 is located at a side of the first STI region 01 away from the second STI region 03, and the fourth STI region 04 is located at a side of the second STI region 02 away from the first STI region side 01; the high voltage P-well (HVPW) between the first STI region 01 and the second STI region 02, and the high voltage P-well (HVPW) on side of the first STI region 01 away from the second STI region 02, and the high voltage P-well (HVPW) on side of the second STI region 02 away from first STI region 01, are active regions; the high voltage P-well (HVPW) between the third STI region 03 and the first STI region 01 and the high voltage P-well (HVPW) between the second STI region 02 and the fourth STI region 04 are active regions; and a first high-voltage region N-diffusion region 05 formed within the high voltage P-well (HVPW) between the first STI region 01 and the second STI region 02;
the active region at the side of the first STI region 01 away from the second STI region 02 and the active region at the side of the second STI region 02 away from the first STI region 01 are formed with a gate oxide layer (GOX/HK); the active region immediately adjacent to the first STI region between the first STI region and second STI region is formed with a first silicon oxide structure 12, and the active region immediately adjacent to the second STI region between the first STI region and the second STI region is formed with a second silicon oxide structure 13; and
an IO N-well (IONW) is formed within the first high-pressure region N-diffusion region 05 of the lower area between the first silicon oxide structure 12 and second silicon oxide structure 13.

Further, in this embodiment, the active region between the third STI region 03 and first STI region 01 is formed with a second high-pressure region N-diffusion region 06 and a first high-pressure region P-diffusion region 07 adjacent to each other; and the active region between the second STI region 02 and fourth STI region 04 is formed with a third high-pressure region N-diffusion region 08 and a second high-pressure region P-diffusion region 09 adjacent to each other.

Further, in this embodiment, a metal gate is formed on the gate oxide layer.

Further, in this embodiment, the first high-voltage region N-diffusion region between the first silicon oxide structure and second silicon oxide structure is formed with a first SDN region 14; the second high-voltage region N-diffusion region 06 is formed with a second SDN region 15; the third high-voltage region N-diffusion region 08 is formed with a third SDN region 16; and the first high-voltage region P-diffusion region 07 is formed with a first SDP region, and the second high-pressure region N-diffusion region 09 is formed with a second SDP region 18.

The present application provides the improvement of ESD device problems of existing high-voltage devices by utilizing high-voltage etch back areas. In this regard, etch back for a partial high-voltage region is performed for a drain region corresponding to a ESD pad area to form a shallow isolation structure, and the implantation of N-well doping (IONW) is performed in a MV (medium-voltage) area, so that low-voltage triggering can be realized, thereby preventing junction drift caused by the Kirk effect at a high voltage. Meanwhile, the high voltage etch back area used in this area is lower than the original shallow slot isolation area, a current can be prevented from approaching a corner of STI. Damage from large currents in a middle area is prevented, thus improving the uniformity, and ultimately the conductivity of the high voltage ESD device. The structure proposed in the present application is compatible with existing processes, with no need for new process development or mask plates.

In summary, ion implantation such as IO N-wells introduced in the present application has a depth larger than that of an active region etch back area to enhance N-type doping in the area, facilitating kirk-effect suppression. Since a utilized active region etch back area which may form a channel restricting a current allows a corresponding current to flow along a heavily doped area to a high voltage P-well area, non-uniform conduction problems due to current crowding at a STI corner can be prevented. The application allows no increase in a layout area by utilizing an original STI region, and at the same time, is compatible with an existing process with no newly added mask plate. Therefore, the present application effectively overcomes the shortcomings in the prior art and has high industrial utilization value.

The above embodiments are merely illustrative of the principles of the present application and effects thereof, and are not intended to limit the present application. Those skilled in the art may modify or change the above embodiments within the spirit and scope of the present application. Therefore, the claims of the present application include all equivalent modifications or changes made by those skilled in the art without departing from the spirit and technical ideas disclosed in the present application.

What is claimed is:

1. A method for improving ESD performance of a metal-gate high-voltage device, at least comprising:
step I. providing a P-substrate, and forming a high voltage P-well on the P-substrate;
Step II. forming a first STI region and a second STI region spaced apart from each other within the high voltage P-well, wherein the high voltage P-well between the first STI region and the second STI region, and the high voltage P-well on side of the first STI region away from the second STI region, and the high voltage P-well on side of the second STI region away from the first STI region, are active regions;
Step III. forming a first high-voltage region N-diffusion region within the high voltage P-well between the first STI region, and second STI region;
Step IV. etching the active region between the first STI region and second STI region to form recesses in the area immediately adjacent to the first STI region and the area immediately adjacent to the second STI region between the first STI region and second STI region; and etching the active region at the side of the first STI region away from the second STI region and the active region at the side of the second STI region away from the first STI region to form a recess;
Step V. filling the recesses with silicon oxide, wherein the silicon oxide in the recess in the side of the first STI region away from the second STI region and the silicon oxide in the recess in the side of the second STI region away from the first STI region are formed as a gate oxide layer; and the silicon oxide in the recess immediately adjacent to the first STI region between the first STI region and second STI region is formed as a first silicon oxide structure, and the silicon oxide in the recess immediately adjacent to the second STI region between the first STI region and second STI region is formed as a second silicon oxide structure; and
Step VI. forming an IO N-well within the first high-pressure region N-diffusion region of the lower area between the first silicon oxide structure and second silicon oxide structure.

2. A method for improving ESD performance of a metal-gate high-voltage device according to claim 1, wherein: a third STI region and a fourth STI region are also formed within the high voltage P-well in step II, wherein the third STI region is located at a side of the first STI region away from the second STI region, the fourth STI region is located at a side of the second STI region away from the first STI region, and the high voltage P-well between the third STI region and first STI region and the high voltage P-well between the second STI region and fourth STI region are active regions.

3. The method for improving ESD performance of a metal-gate high-voltage device according to claim 2, wherein in step III, a second high-voltage region N-diffusion region and a first high-voltage region P-diffusion region adjacent to each other are formed in the active region between the third STI region and first STI region; and a third high-voltage region N-diffusion region and a second high-pressure region P-diffusion region adjacent to each other are formed in the active region between the second STI region and fourth STI region.

4. A method for improving ESD performance of a metal-gate high-voltage device according to claim 3, wherein the method further comprises step VII. forming a metal gate on the gate oxide layer.

5. The method for improving ESD performance of a metal-gate high-voltage device according to claim 4, wherein the method further comprises step VIII. forming a first SDN region in the first high-voltage region N-diffusion region between the first silicon oxide structure and second silicon oxide structure; forming a second SDN region on the second high-voltage region N-diffusion region; forming a third SDN region on the third high-voltage region N-diffusion region; and forming a first SDP region in the first high voltage region P-diffusion region, and forming a second SDP region in the second high voltage region P-diffusion region.

6. A structure for improving ESD performance of a metal-gate high-voltage device, at least comprising:
a P-substrate, and a high voltage P-well located on the P-substrate; a first STI region, a second STI region, a third STI region, and a fourth STI region spaced apart from each other within the high voltage P-well; wherein the third STI region is located at a side of the first STI region away from the second STI region, and the fourth STI region is located at a side of the second STI region away from the first STI region; the high voltage P-well between the first STI region and the second STI region, and the high voltage P-well on side of the first STI region away from the second STI region, and the high voltage P-well on side of the second STI region away from the first STI region, are active regions; and the high voltage P-well between the third STI region and first STI region and the high voltage P-well between the second STI region and fourth STI region are active regions; and a first high-voltage region N-diffusion region formed within the high voltage P-well between the first STI region and second STI region; and
the active region at the side of the first STI region away from the second STI region and the active region at the side of the second STI region away from the first STI region being formed with a gate oxide layer; and the active region immediately adjacent to the first STI region between the first STI region and second STI region being formed with a first silicon oxide structure, and the active region immediately adjacent to the second STI region between the first STI region and the second STI region being formed with a second silicon oxide structure; and
an IO N-well being formed within the first high-pressure region N-diffusion region of the lower area between the first silicon oxide structure and second silicon oxide structure.

7. A structure for improving ESD performance of a metal-gate high-voltage device according to claim 6, wherein: the active region between the third STI region and first STI region is formed with a second high-voltage region N-diffusion region and a first high-voltage region P-diffusion region adjacent to each other; and the active region between the second STI region and fourth STI region is formed with a third high-voltage region N-diffusion region and a second high-voltage region P-diffusion region adjacent to each other.

8. A structure for improving ESD performance of a metal-gate high-voltage device according to claim 6, wherein: a metal gate is formed on the gate oxide layer.

9. The structure for improving ESD performance of a metal-gate high-voltage device according to claim 6, wherein the first high-voltage region N-diffusion region between the first silicon oxide structure and second silicon oxide structure is formed with a first SDN region; the second high-voltage region N-diffusion region is formed with a second SDN region; the third high-voltage region N-diffusion region is formed with a third SDN region; and the first high-voltage region P-diffusion region is formed with a first SDP region, and the second high-pressure region P-diffusion region is formed with a second SDP region.
